(19) United States
(12) Patent Application Publication
(10) Pub. No.: US 2022/0074043 A1
(43) Pub. Date: Mar. 10, 2022

(54) INITIAL TREATMENT METHOD FOR TARGET MATERIAL FOR PHYSICAL VAPOR DEPOSITION PROCESS, AND CONTROLLER

(71) Applicant: CHANGXIN MEMORY TECHNOLOGIES, INC., Hefei City (CN)

(72) Inventors: Renlong LI, Hefei (CN); NUNG-CHAN WANG, Hefei (CN)

(73) Assignee: CHANGXIN MEMORY TECHNOLOGIES, INC., Hefei City (CN)

(21) Appl. No.: 17/445,231

(22) Filed: Aug. 17, 2021

Related U.S. Application Data
(63) Continuation of application No. PCT/CN2021/101632, filed on Jun. 22, 2021.

(30) Foreign Application Priority Data
Sep. 4, 2020 (CN) 202010921775.8

(51) Int. Cl. C23C 14/34

(52) U.S. Cl. CPC C23C 14/3414

(57) ABSTRACT

A method for initial treatment of a target material based on a physical vapor deposition (PVD) process and a controller includes: enhancing a turn-on current on a new target material multiple times from zero to a preset current. The method for initial treatment of a target material provided by the disclosure can avoid the occurrence of electric arc causing downtime for maintenance when the new target material participates in a cavity cleaning process.

### CROSS-REFERENCE TO RELATED APPLICATIONS

This is a continuation application of International Patent Application No. PCT/CN2021/101632, filed on Jun. 22, 2021, which claims priority to China Patent Application No. 202010921775.8, filed on Sep. 4, 2020. The disclosures of these applications are hereby incorporated by reference in their entireties.

### BACKGROUND

A physical vapor deposition (PVD) process refers to the use of low-voltage high-current arc discharge technology under a vacuum condition, the use of gas discharge to evaporate a target material, and ionize the evaporated substance and gas. The evaporated substances and its reaction products are deposited on a workpiece under the action of the acceleration of an electric field.

### SUMMARY

The disclosure relates generally to the field of semiconductor manufacturing technologies, and more specifically to a method for initial treatment of a target material used in a physical vapor deposition process, and a controller.

The disclosure is directed to provide a method for initial treatment of a target material and an initial treatment device for a target material, so as to at least solve, to a certain extent, the problem of arc alarm caused by a new target material being electrified due to restrictions and defects of the related art.

According to a first aspect of the embodiments of the disclosure, a method for an initial treatment of a target material, including: enhancing a turn-on current on a new target material multiple times from zero to a preset current.

In an example embodiment of the disclosure, each said enhancing is preceded by a pause of a first preset time.

In an example embodiment of the disclosure, durations of each of the first preset time are the same or different.

In an example embodiment of the disclosure, each time the turn-on current is enhanced, each turn-on current is controlled to reach a target current within a second preset time, and durations of the second preset time are the same or different.

In an example embodiment of the disclosure, the preset current value is m; the enhancing a turn-on current on a new target material multiple times from zero to a preset current may include: enhancing the turn-on current from zero n times; each time the turn-on current is enhanced by a value that is not greater than m/n, where m and n are both positive integers, and n≥2.

In an example embodiment of the disclosure, the enhancing a turn-on current on the new target material multiple times from zero to a preset current may include: in response to an electrification signal of the new target material, controlling a constant current source to sequentially output a first current to an nth current from low to high until the preset current is output, n≥2. A duration for outputting each current from the first current to the nth current is 30 s to 60 s.

In an example embodiment of the disclosure, the enhancing a turn-on current on the new target material multiple times from zero to a preset current may include: in response to an electrification signal of the new target material, controlling a plurality of constant current sources connected to the new target material to be initiated in sequence. An interval between initiation times of two adjacent constant current sources is 30 s to 60 s.

In an example embodiment of the disclosure, working gas is continuously fed in a process of enhancing the turn-on current to the preset current.

In an example embodiment of the disclosure, the enhancing a turn-on current on a new target material multiple times from zero to a preset current may include: in response to an electrification signal of the new target material, controlling a constant voltage source connected to the new target material to output a first voltage to an nth voltage from low-to-high in sequence until a preset voltage corresponding to the preset current is output, n≥2, and a duration of the first voltage to the nth voltage is equal, which is 30 s to 60 s; or, in response to an electrification signal of the new target material, controlling a plurality of constant voltage sources connected to the new target material to be initiated in sequence. A voltage output by each of the constant voltage source is the same, and an interval between the initiation times of two adjacent constant voltage sources is 30 s to 60 s.

According to a second aspect of the disclosure, a controller for a physical vapor deposition (PVD) process is provided, which is used to execute any one of the above-mentioned initial treatment methods for a target material.

It should be understood that the above general description and the following detailed description are exemplary and explanatory only, and are not intended to limit the disclosure.

### BRIEF DESCRIPTION OF THE DRAWINGS

The accompanying drawings, which are incorporated in and constitute a part of this specification, illustrate embodiments consistent with the disclosure and, together with the specification, serve to explain the principles of the disclosure. Apparently, the drawings in the following description are only some embodiments of the disclosure. Those of ordinary skill in the art can further obtain other drawings based on these drawings without creative work.

FIG. 1 is a schematic diagram illustrating that an arc appears after first use of a new target material.

FIG. 2 is a schematic diagram of a method for an initial treatment of a target material in some embodiments of the disclosure.

FIG. 3 is a schematic diagram of a method for an initial treatment of a target material in some other embodiments of the disclosure.

FIG. 4 is a schematic effect diagram of the embodiments of the disclosure.

### DETAILED DESCRIPTION

Example implementation modes will be now described below more comprehensively with reference to the accompanying drawings. However, the example implementation modes can be embodied in a variety of forms and should not be construed as being limited to the examples set forth herein. Rather, these implementation modes are provided to make the disclosure more comprehensive and complete, and fully convey the concept of the exemplary implementation modes to those skilled in the art. The features, structures or characteristics described may be combined in one or more implementation modes in any proper manner. In the following description, many specific details are provided to give a sufficient understanding of the implementation modes of the disclosure. However, those skilled in the art will realize that the technical solutions of the disclosure can be practiced without one or more of the specific details, or other methods, components, devices, steps, etc. can be used. In other cases, the well-known technical solutions are not shown or described in detail to avoid distraction and obscuring of all aspects of the disclosure.

In addition, the drawings are only schematic illustrations of the disclosure, and the same reference signs in the drawings denote the same or similar parts, and thus their repeated descriptions will be omitted. Some of the block diagrams shown in the drawings are functional entities and do not necessarily correspond to physically or logically independent entities. These functional entities may be implemented in the form of software, or implemented in one or more hardware modules or integrated circuits, or implemented in different networks and/or processor devices and/or microcontroller devices.

Exemplary implementation modes of the disclosure will be described in detail below with reference to the accompanying drawings.

A PVD process may need to be implemented in an environment with high vacuum and high cleanliness requirements. Since a metal target material is a consumable, when an old target material is consumed to a limit, a cavity needs to be opened and replaced with a new target material. This will inevitably lead to a decrease in the cleanliness in the cavity. Therefore, it may be necessary to use an auxiliary wafer to perform the PVD process to clean the cavity every time a new target material is replaced. When the cavity is cleaned, it is necessary to connect the new target material that participates in the PVD process for the first time to a positive electrode of a power supply and apply a preset current to attract argon molecules of a negative electrode to hit the new target material, such that metal particles fall onto a surface of the auxiliary wafer.

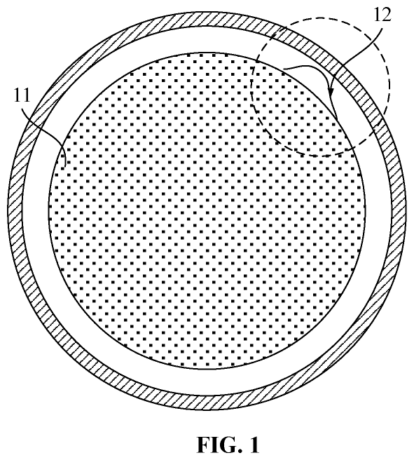

In this process, as oxides are often present on the surface of the new target material, overheating often occurs after electrification, and an arc 12 as shown in FIG. 1 (11 represents the new target material in FIG. 1) appears, which causes a DC power fail alarm and in turn leads to the termination of the process and affects the cleaning of the cavity and the subsequent manufacturing processes.

In the embodiments of the disclosure, a target material that is put into operation for the first time is called a new target material.

As shown in FIG. 1, when the new target material 11 is put into operation for the first time, an arc 12 will often occur. This phenomenon often leads to power fail alarm, which results in the interruption of a cavity cleaning process. The literature in this field does not give a cause and a solution of this problem. In order to determine the cause of the problem, the inventor of the present application tested various indicators of the cavity cleaning process and conducted a variety of experiments, and finally determined that the cause of this problem was due to the presence of oxides on a surface of the new target material. Direct feeding of a preset current will lead to the overheat of the new target material and result in an arc phenomenon. After multiple experiments, the inventor of the present application determined that enhancing a turn-on current on the new target material multiple times from zero to a preset current can avoid the occurrence of the arc and the power fail alarm.

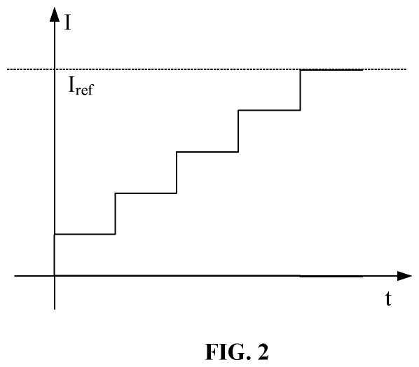

FIG. 2 is a schematic diagram of a method for an initial treatment of a target material in the exemplary embodiments of the disclosure.

Referring to FIG. 2, in the embodiments of the disclosure, the turn-on current on the new target material is enhanced multiple times from zero to a preset current Iref.

For example, when the value of the preset current is m, the turn-on current can be enhanced from zero for n times. It is set that the turn-on current is enhanced by a value that is not greater than m/n at each time, where m and n are both positive integers, and n≥2.

In one embodiment, the preset current Iref can be, for example, 5 A. In the related art, a physical vapor deposition (PVD) process cannot be implemented until the turn-on current on the target material is 5 A. Before the PVD process is implemented on the new target material by formally using the preset current, the turn-on current on the new target material can be enhanced to 5 A in 5 steps from zero. As shown in FIG. 2, the turn-on current can be first controlled to be 1 A. After a period of time, the turn-on current is controlled to be 2 A, etc., the turn-on current is controlled to be from 3 A to 4 A to 5 A multiple times.

In one embodiment, in response to an electrification signal of the new target material, a constant current source can be controlled to output a first current to an nth current from low to high in sequence until the preset current is output, n≥2. A duration of the first current to the nth current is equal, which is 30 s to 60 s.

In another embodiment, it can also be set that the new target material can be connected to a plurality of constant current sources, and each constant current source outputs the same current, such that the turn-on current can gradually increase by controlling the plurality of constant current sources to be initiated in sequence. An initiation time interval between two adjacent constant current sources can be set to be 30 s to 60 s. In one embodiment, the time interval can be controlled to be 30 s.

In addition, the method provided in the disclosure can also be realized by controlling a constant voltage source. When a constant voltage source is used, a resistance value of a resistor corresponding to the constant voltage source needs to be kept unchanged.

For example, in response to an electrification signal of the new target material, a constant voltage source can be controlled to output a first voltage to an nth voltage from low to high in sequence until a preset voltage corresponding to the preset current is output, n>2. A duration of the first voltage to the nth voltage is equal, which is 30 s to 60 s.

Corresponding to the embodiment of the constant current source, in response to the electrification signal of the new target material, a plurality of constant voltage sources connected to the new target material can be controlled to be initiated in sequence. A voltage output by each constant voltage source is the same. An interval between initiation time of two adjacent constant voltage sources is 30 s to 60 s.

It can be understood that although an amplitude of a waveform of the turn-on current corresponding to each value in FIG. 2 is a single value, in actual applications, even if the current is set to be a single value, a resistance of the new target material is affected by temperature, which will also cause a small change in the amplitude of the waveform of the turn-on current. For example, the amplitude increases unidirectionally from low to high (that is, the current waveform has an upward slope at a stage corresponding to each turn-on current value). This situation also falls within the protection scope of the disclosure.

The turn-on current is raised stepwise, and the previous current is allowed to continue for a period of time before each rise, which can effectively prevent the new target material from overheating and generating an arc.

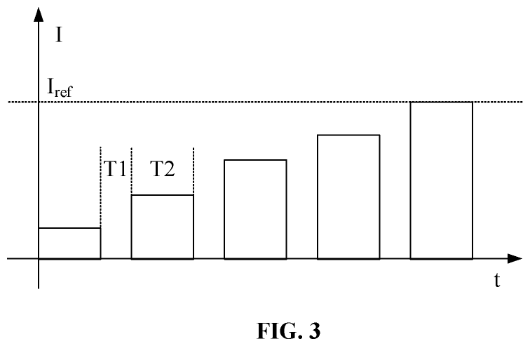

FIG. 3 is a schematic diagram of another embodiment of the disclosure.

Referring to FIG. 3, in another embodiment, the enhancement is paused for a first preset time T1 each time before enhancing the turn-on current. The first preset time T1 of the pause before each enhancement of the turn-on current can be the same or different. For example, after a turn-on current of an intermediate value i output at each time, outputting of the current is paused for 30 s, and a higher current of the next stage is output. In addition, the pause time can be set to be shorter after a lower current is output. The pause time is prolonged after the higher current (close to the preset current Iref) is output, so as to provide enough time for the new target material to adjust surface thermal stress.

In addition, as shown in FIG. 3, it can also be possible to control each of the turn-on currents to reach a target current within a second preset time T2 each time the turn-on current is enhanced, and each of the second preset time is the same or different. In addition to controlling each output turn-on current to directly reach a target value of this stage, it can also be set in the T2 time period that the turn-on current reaches the target value of this stage, that is, the current waveform corresponding to the time period T2 in FIG. 3, for example, can be a slope.

In the embodiment shown in FIG. 3, increase of the turn-on current can also be realized by changing the output value of the constant current source multiple times, increasing the number of working constant current sources multiple times, changing the output value of the constant voltage source multiple times, increasing the number of working constant voltage sources multiple times, etc. Descriptions thereof are omitted here in the disclosure.

No matter which embodiment mentioned above is used to achieve rise of the turn-on resistance, working gas (for example, argon) can be continuously fed in the process of enhancing the turn-on current to the preset current. In one embodiment, a flow of argon that is continuously fed can be set to 50 sccm, so as to provide a sufficient power ignition environment.

The method shown in FIG. 2 or FIG. 3 can be implemented by modifying a burn in macro of a PVD process controller. A gradual current raising step can be added before an original macro to slowly increase the current to prevent arcing and prevent damage to the new target material due to a high temperature.

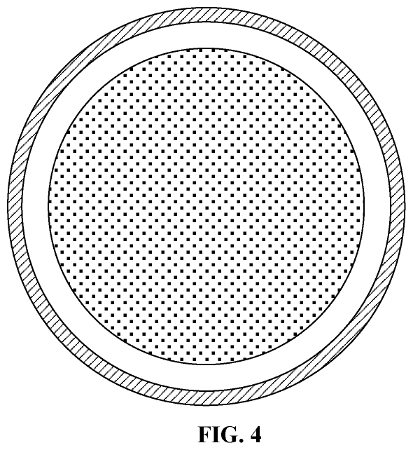

FIG. 4 is a schematic implementation effect diagram of the embodiments of the disclosure.

Referring to FIG. 4, after many experiments and adjustment of current parameters and time parameters, after the turn-on current on the new target material is gradually increased according to the method in the embodiment shown in FIG. 2 or FIG. 3, the new target material successfully participates in the cavity cleaning process and participates in cleaning a rear surface, so there is no arc trace.

The method provided by the embodiments of the disclosure can be written into a PVD process implementation controller in the form of a burn in macro, such that after a new target material installation signal and an electrification signal of the new target material are detected, the methods corresponding to the above embodiments are realized to finally apply the preset current to the new target material. Finally, the cavity cleaning process participated by the new target material is completed by the preset current.

In summary, by means of gradually enhancing the turn-on current on the new target material from zero to a preset current, the embodiments of the disclosure solves unsolved problems of interruption of the cavity cleaning process and downtime overhaul due to the arc generated by the new target material in the cavity cleaning process in the related art, thereby effectively reducing a fault rate of a semiconductor manufacturing process and improving the efficiency of the semiconductor manufacturing process.

In addition, the above-mentioned drawings are merely schematic illustrations of the treatment included in the method according to the exemplary embodiments of the disclosure, and are not intended for limitation. It is easy to understand that the treatment shown in the above drawings does not indicate or limit the time sequence of these treatments. In addition, it is easy to understand that these treatments can be executed synchronously or asynchronously in multiple modules, for example.

After considering the specification and implementing the disclosure disclosed here, those skilled in the art will easily conceive other implementation solutions of the disclosure. The present application is intended to cover any variations, uses, or adaptive changes of the disclosure. These variations, uses, or adaptive changes follow the general principles of the disclosure and include common general knowledge or conventional technical means in the technical field, which are not disclosed herein. The specification and embodiments are only regarded as exemplary, the true scope and concept of the disclosure are indicated by the claims.

In the embodiments of the disclosure, by enhancing the turn-on current on the new target material multiple times from zero to a preset current, it is possible to avoid the occurrence of electric arc caused by the oxides on a surface on the new target material during initial use and causing the failure of a cavity cleaning process due to the cavity voltage failure alarm.

What is claimed is:

1. A method for initial treatment of a target material based on a physical vapor deposition (PVD) process, comprising:
enhancing a turn-on current on a new target material multiple times from zero to a preset current.

2. The method for initial treatment of a target material of claim 1, wherein each said enhancing is preceded by a pause of a first preset time.

3. The method for initial treatment of a target material of claim 2, wherein durations of the first preset time are same or different.

4. The method for initial treatment of a target material of claim 1, wherein, each time the turn-on current is enhanced, each turn-on current is controlled to reach a target current within a second preset time, and durations of the second preset time are same or different.

5. The method for initial treatment of a target material of claim 1, wherein the preset current value is m; the enhancing a turn-on current on a new target material multiple times from zero to a preset current comprises:
enhancing the turn-on current from zero n times; each time the turn-on current is enhanced by a value that is not greater than m/n, wherein m and n are both positive integers, and n≥2.

6. The method for initial treatment of a target material of claim 1, wherein the enhancing a turn-on current on the new target material multiple times from zero to a preset current comprises:
in response to an electrification signal of the new target material, controlling a constant current source to sequentially output a first current to an nth current from low to high until the preset current is output, n≥2, wherein a duration for outputting each current from the first current to the nth current is 30 s to 60 s.

7. The method for initial treatment of a target material of claim 1, wherein the enhancing a turn-on current on the new target material multiple times from zero to a preset current comprises:
in response to an electrification signal of the new target material, controlling a plurality of constant current sources connected to the new target material to be initiated in sequence; and an interval between initiation time of two adjacent constant current sources is 30 s to 60 s.

8. The method for initial treatment of a target material of claim 1, wherein working gas is continuously fed in a process of enhancing the turn-on current to the preset current.

9. The method for initial treatment of a target material of claim 1, wherein the enhancing a turn-on current on the new target material multiple times from zero to a preset current comprises:
in response to an electrification signal of the new target material, controlling a constant voltage source connected to the new target material to output a first voltage to an nth voltage from low to high in sequence until a preset voltage corresponding to the preset current is output, n≥2; and a duration of the first voltage to the nth voltage is equal, which is 30 s to 60 s.

10. The method for initial treatment of a target material of claim 1, wherein the enhancing a turn-on current on the new target material multiple times from zero to a preset current comprises:
in response to an electrification signal of the new target material, controlling a plurality of constant voltage sources connected to the new target material to be initiated in sequence, wherein a voltage output by each constant voltage source is the same; and an interval between the initiation times of two adjacent constant voltage sources is 30 s to 60 s.

11. A controller for a physical vapor deposition (PVD) process, wherein the controller is configured to execute the method for initial treatment of a target material according to claim 1.
